(19) United States
(12) Patent Application Publication
(10) Pub. No.: US 2006/0044767 A1
(43) Pub. Date: Mar. 2, 2006

(54) Peripheral component interconnection (PCI) riser card positioning structure of computer server

(75) Inventors: Chia-Kang Wu, Taipei City (TW); Yu-Jen Liang, Taipei City (TW); Fu-Jung Hsui, Taipei City (TW)

Correspondence Address: BACON & THOMAS, PLLC, 625 SLATERS LANE, FOURTH FLOOR, ALEXANDRIA, VA, 22314, US

(73) Assignee: Tatung Co., Ltd., Taipei City (TW)

(21) Appl. No.: 11/197,416

(22) Filed: Aug. 5, 2005

(30) Foreign Application Priority Data
Aug. 31, 2004 (TW) 093213799

(51) Int. Cl. H05K 7/16

(52) U.S. Cl. 361/725

(57) ABSTRACT

A computer server having a motherboard with a PCI riser card slot between a first upright bracket and a second upright bracket is disclosed a PCI riser card positioning structure, which includes a first locating hole formed in the top flange of the first upright bracket, a second locating hole formed in the top flange of the second upright bracket, and a auxiliary bracket bridged between the first upright bracket and the second upright bracket, the auxiliary bracket having a longitudinal panel and a PCI riser card mounted on the bottom side of the longitudinal panel, which having a mounting device and a locating plug respectively disposed at the two distal ends thereof and respectively fastened to the first locating hole and the second locating hole to guide the PCI riser card engaging into the PCI riser card slot for electrical connection.

### BACKGROUND OF THE INVENTION

1. Field of the Invention

The present invention relates to a peripheral component interconnection (PCI) riser card positioning structure and more particularly, to a PCI riser card positioning structure used in a computer server.

2. Description of Related Art

Different firms for the advantage of standardized machine size convenient for management in a machine room to fully utilize the floor space of the limited machine room popularly accept computer servers.

Generally, the case of a computer server has a flat shape for easy access to a rack. Because of flat outer appearance, the utilization of the internal space of a computer server is limited. A regular personal computer generally has a number of PCI (Peripheral Component Interconnection) slots. To have a better space utilization in a computer server, the installation of PCI riser cards must be properly designed. The way to guide a 3-card single-side type PCI riser card into position in a computer server is not important. Many designs in this regard have been disclosed, and have appeared on the market. However, the guidance of a 6-card double-side type PCI riser card is very important. Because a PCI riser card of this design has many PCI slots at two sides, the user may be unable to see the relative position between the gold fingers of the PCI riser card and the PCI riser card slot on the motherboard when the PCI slots of the PCI riser card are all mounted with a respective PCI card. In proper installation of the PCI riser card in the PCI riser card slot on the motherboard may damage the PCI riser card or the motherboard.

As illustrated in FIG. 1, the gold fingers 111 of the PCI riser card 11 are inserted into the PCI riser card slot 121 on the motherboard 12. The PCI riser card 11 has a plurality of PCI slots 112 at two sides. When inserting the PCI riser card 11 vertically into the PCI riser card slot 121, and other PCI cards 113 are horizontally maintained in the PCI slots 112. Therefore, when the PCI slots 112 of the PCI riser card 11 are all mounted with a respective PCI card 113, the user cannot visually aim the gold fingers 111 at the PCI riser card slot 121. At this time, it is difficult to accurately insert the PCI riser card 11 into the PCI riser card slot 121, and the gold fingers 111 or the motherboard 12 may be damaged accidentally during installation of the PCI riser card 11 in the PCI riser card slot 121.

### SUMMARY OF THE INVENTION

The present invention has been accomplished under the circumstances in view. It is therefore the main object of the present invention to provide a peripheral component interconnection (PCI) riser card positioning structure, which enables the user to quickly and accurately install a PCI riser card in a PCI riser card slot of a computer server's motherboard.

To achieve this and other objects of the present invention, the PCI riser card positioning structure is used in a computer server, which comprises a bottom panel, a first upright bracket, a second upright bracket opposite to the first upright bracket, and a motherboard mounted on the bottom panel. The motherboard comprises a PCI riser card slot disposed at a top side thereof between the first and second upright brackets. The first and second upright brackets each have a top flange. The PCI riser card positioning structure comprises a first locating hole, a second locating hole, and an auxiliary. The first locating hole formed in the top flange of the first upright bracket, the second locating hole formed in the top flange of the second upright bracket, the auxiliary bracket bridged between the top flanges of the first upright bracket and the second upright bracket. The auxiliary bracket comprises a longitudinal panel and a PCI riser card mounted on the bottom side of the longitudinal panel. The longitudinal panel has a mounting device and a locating plug respectively disposed at two distal ends thereof and respectively fastened to the first locating hole and the second locating hole to guide the PCI riser card engaging into the PCI riser card slot for electrical connection.

In general, the PCI riser card positioning structure of the present invention is to provide a locating hole at an upright bracket inside the computer server, and a locating plug at the side of the PCI riser card for insertion into the locating hole at the upright bracket inside the computer server before insertion of the PCI riser card into the PCI riser card slot so that the gold fingers of the PCI riser card can be accurately guided into the PCI riser card slot after insertion of the locating plug into the locating hole.

### BRIEF DESCRIPTION OF THE DRAWINGS

FIG. 1 illustrates a PCI riser card installed in a computer server according to the prior art.

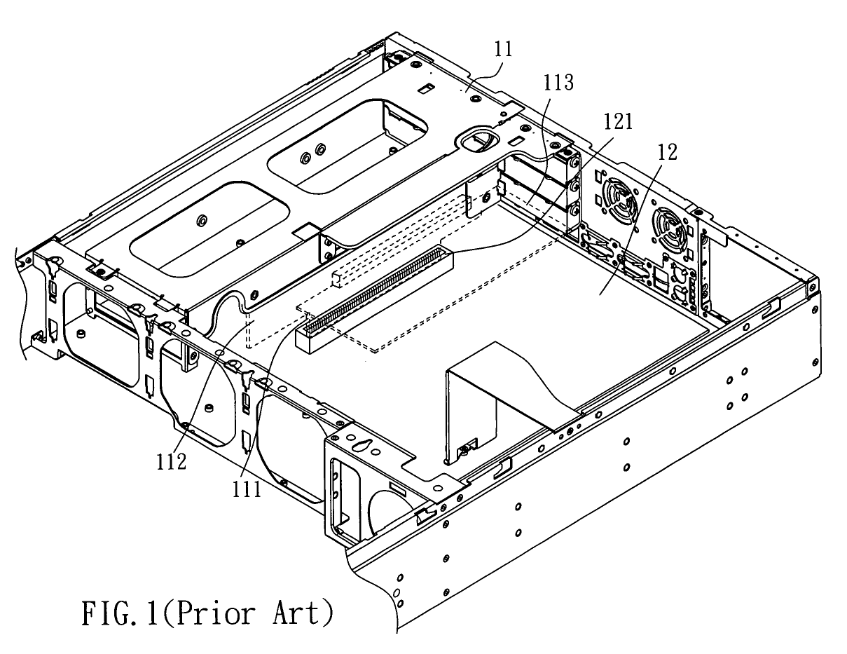

FIG. 2 is an exploded view of a PCI riser card positioning structure according to the present invention.

FIG. 3 is an enlarged view of a part of FIG. 2.

### DETAILED DESCRIPTION OF THE PREFERRED EMBODIMENT

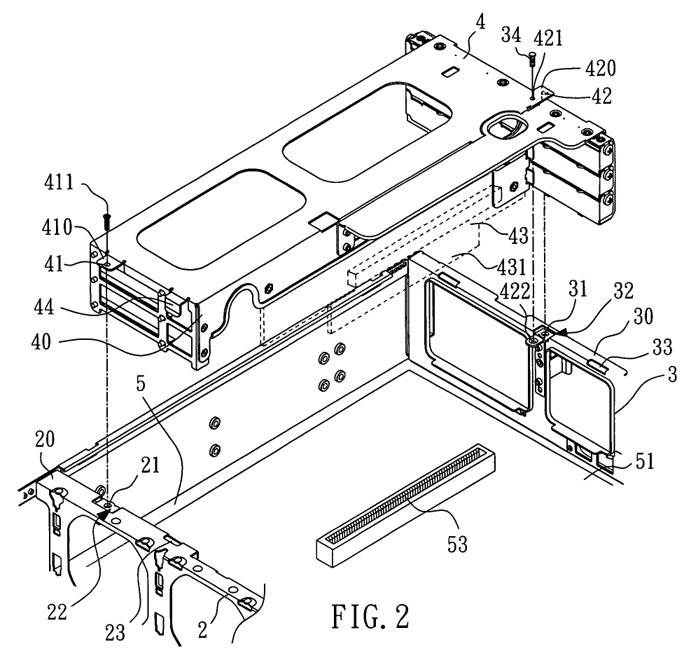

Referring to FIG. 2, a computer server comprises a bottom panel 5, two upright brackets 2,3 opposing each other at two sides, and a motherboard 51 mounted on the bottom panel 5. The motherboard 51 comprises a PCI (Peripheral Component Interconnection) riser card slot 53 disposed at the top side between the two upright brackets 2,3 and extended in longitudinal direction, i.e., the direction from one upright bracket 2 toward the other bracket 3. Each of the upright brackets 2, 3 has a perpendicularly extended top flanges 20,30. Each of the top flanges 20,30 has a recessed portion 22,32, and a locating hole 21,31 in the recessed portion 22,32.

An auxiliary bracket 4 is bridged between the top flanges 20,30 of the upright bracket 2 and the upright bracket 3 of the computer server. The auxiliary bracket 4 comprises a longitudinal panel 40, and a PCI riser card 43. The PCI riser card 43 is provided at the bottom side of the longitudinal panel 40, having a downwardly extended gold finger portion 431. The auxiliary bracket 4 further comprises two lugs 410,420 symmetrically disposed at two sides corresponding to the recessed portions 22,32 of the top flanges 20,30 of the upright brackets 2,3. One lug 410 has a screw hole 41 corresponding to the locating hole 21 in the recessed portion 22 of the top flange 20 of one upright bracket 2. The other lug 420 has a locating plug 42 downwardly extended from the bottom side corresponding to the locating hole 31 in the recessed portion 32 of the top flange 30 of the other upright bracket 3. The PCI riser card 43 is connectable to the PCI riser card slot 53 of the motherboard 51.

When inserting the PCI riser card 43 into the PCI riser card slot 53 of the motherboard 51, the user does not need to aim the gold finger portion 431 at the PCI riser card slot 53 of the motherboard 51 visually like the prior art design. The user needs only to insert the locating plug 42 into the locating hole 31 in the recessed portion 32 of the top flange 30 of the respective upright bracket 3 and then secure a screw 411 to the screw hole 41 of the auxiliary bracket 4 and the locating hole 21 in the recessed portion 22 of the top flange 20 of the respective upright bracket 2, and the PCI riser card 43 is automatically accurately inserted into the PCI riser card slot 53 of the motherboard 51 for electrical connection.

In order to enhance the installation stability of the PCI riser card 43, a through hole 421 is formed in the auxiliary bracket 4 adjacent to the lug 420, and a screw 422 is inserted through the through hole 421 and threaded into a screw holder 34 at the upright bracket 3 to affix the auxiliary bracket 4 to the upright bracket 3.

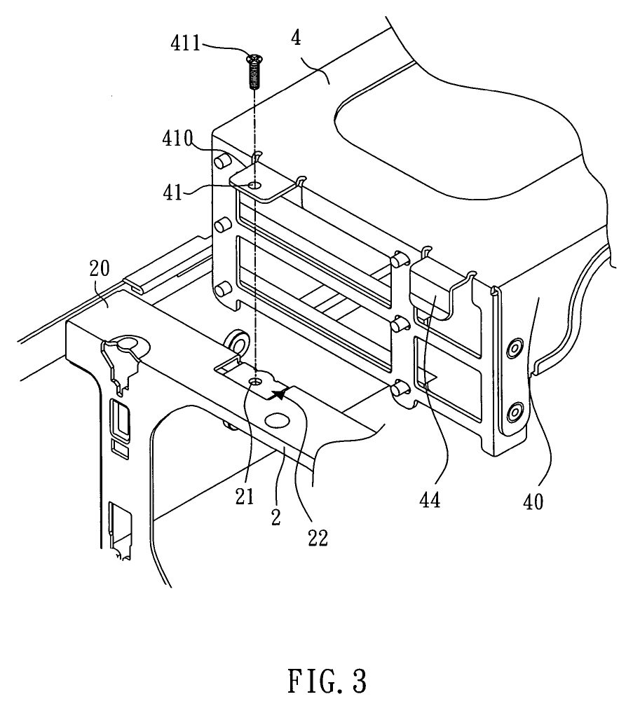

Referring to FIG. 3 and FIG. 2 again, in addition to the advantage of ease of alignment, the invention also provides a measure to reduce error. As illustrated, the locating hole 31 in the recessed portion 32 of the top flange 30 of the upright bracket 3 is a circular hole, and the locating plug 42 is a round pin fitting the circular locating hole 31 in the recessed portion 32 of the top flange 30 of the upright bracket 3. The design concept of the present invention is used the locating plug 42 to position in transverse (major axis) direction, and then to use the screw hole 41 and the screw 4 for locking to prevent positioning error in transverse direction, thereby ensuring accurate insertion of the PCI riser card 43 into the PCI riser card slot 53. The locating plug 42 in insertable into the locating hole 31 either in X-axis or Y-axis direction. After insertion of the locating plug 42 into the locating hole 31, the locating plug 42 can be freely rotated in the locating hole 31, however the screw hole 41 has only one degree of freedom at this time. Therefore, the invention prevents displacement of the PCI riser card 43 between the two locating members locating plug.

Referring to FIG. 2 again, each of the top flanges 20,30 of the upright brackets 2,3 further has a retaining hole 23, 33; the longitudinal panel 40 of the auxiliary bracket 4 has two downward hooks 44 respectively extended from the two distal ends of the longitudinal panel 40 and hooked in the retaining holes 23,33 of the upright brackets 2,3 correspondingly to enhance the tightness of the connection between the PCI riser card 43 and the PCI riser card slot 53. The downward hooks 44 can be made of any of a variety of suitable materials, preferably springy material.

As indicated above, the invention provides a PCI riser card positioning structure, which enables the user to rapidly install a PCI riser card in a computer server and accurately positively connect the PCI riser card to a PCI riser card slot in the motherboard of the computer server. The design of the present invention saves much PCI riser card installation time, preventing mechanical damage due to an installation error.

Although the present invention has been explained in relation to its preferred embodiment, it is to be understood that many other possible modifications and variations can be made without departing from the spirit and scope of the invention as hereinafter claimed.

What is claimed is:

1. A peripheral component interconnection (PCI) riser card positioning structure used in a computer server, said computer server comprises a bottom panel, a first upright bracket, a second upright bracket opposite to said first upright bracket, and a motherboard mounted on said bottom panel, said motherboard comprising a PCI riser card slot disposed at a top side thereof between said first upright bracket and said second upright bracket, said first upright bracket and said second upright bracket each having a top flange; the PCI riser card positioning structure comprising:
a first locating hole formed in the top flange of said first upright bracket;
a second locating hole formed in the top flange of said second upright bracket; and
an auxiliary bracket bridged between the top flanges of said first upright bracket and said second upright bracket, said auxiliary bracket comprising a longitudinal panel and a PCI riser card mounted on a bottom side of said longitudinal panel, said longitudinal panel having a mounting device and a locating plug respectively disposed at two distal ends thereof and respectively fastened to said first locating hole and said second locating hole to guide said PCI riser card engaging into said PCI riser card slot for electrical connection.

2. The PCI riser card positioning structure as claimed in claim 1, wherein said mounting device of said auxiliary bracket comprises a hole formed in one end of said longitudinal panel, and a screw secured to said hole and said first locating hole to affix said auxiliary bracket to said first upright bracket.

3. The PCI riser card positioning structure as claimed in claim 1, wherein said first upright bracket and said second upright bracket each further comprises a retaining hole respectively formed in the respective top flange; said auxiliary bracket further comprises two downward hooks respectively extended from the two distal ends of said longitudinal panel and hooked in the retaining holes of said first upright bracket and said second upright bracket correspondingly.

4. The PCI riser card positioning structure as claimed in claim 3, wherein said downward hooks of said auxiliary bracket are springy hooks.

5. The PCI riser card positioning structure as claimed in claim 1, wherein said first upright bracket and said second upright bracket each further comprises a recessed portion respectively formed in the respective top flange; said first locating hole and said second locating hole are respectively formed in the recessed portions of said first upright bracket and said second upright bracket; said auxiliary bracket comprises two lugs respectively extended from the two distal ends of said longitudinal panel and respectively fitted into the recessed portions of said first upright bracket and said second upright bracket.
